(19) United States
(12) Patent Application Publication
(10) Pub. No.: US 2025/0096051 A1
(43) Pub. Date: Mar. 20, 2025

(54) PACKAGE COMPRISING A SUBSTRATE WITH CAVITY, AND AN INTEGRATED DEVICE LOCATED IN THE CAVITY OF THE SUBSTRATE

(71) Applicant: QUALCOMM Incorporated, San Diego, CA (US)

(72) Inventors: Jaehyun YEON, San Diego, CA (US); Kun FANG, San Diego, CA (US); Suhyung HWANG, Rancho Mission Viejo, CA (US); Sang-Jae LEE, San Diego, CA (US); Rajneesh KUMAR, San Diego, CA (US); Manuel ALDRETE, Encinitas, CA (US); Zhijie WANG, San Diego, CA (US); Seongho KIM, San Diego, CA (US)

(21) Appl. No.: 18/471,069

(22) Filed: Sep. 20, 2023

(51) Int. Cl. H01L 23/13; H01L 23/00; H01L 23/31; H01L 23/373; H01L 23/498; H01L 25/16

(52) U.S. Cl. CPC H01L 23/13; H01L 23/3107; H01L 23/3736; H01L 23/49822; H01L 23/49838; H01L 24/16; H01L 24/32; H01L 24/73; H01L 25/16; H01L 2224/16145; H01L 2224/16227; H01L 2224/32145; H01L 2224/32225; H01L 2224/32245; H01L 2224/73204; H01L 2224/73253; H01L 2924/15153

(57) ABSTRACT

A package comprising a first substrate; a first integrated device coupled to the first substrate through at least a first plurality of solder interconnects; a second substrate coupled to the first substrate through at least a second plurality of solder interconnects, wherein the second substrate includes a cavity; and an encapsulation layer located at least between the first substrate and the second substrate, wherein the encapsulation layer is coupled to the first substrate, the second substrate and the first integrated device.

### FIELD

Various features relate to packages with a substrate and an integrated device.

### BACKGROUND

A package may include a substrate and integrated devices. These components are coupled together to provide a package that may perform various electrical functions. These components may generate a lot of heat which has to be efficiently dissipated, since too much heat can negatively affect the performance of integrated devices and/or a package. There is an ongoing need to provide improved heat dissipation in packages, better performing packages and reduce the overall size of the packages.

### SUMMARY

Various features relate to packages with a substrate and an integrated device.

One example provides a package comprising a first substrate; a first integrated device coupled to the first substrate through at least a first plurality of solder interconnects; a second substrate coupled to the first substrate through at least a second plurality of solder interconnects, wherein the second substrate includes a cavity; and an encapsulation layer located at least between the first substrate and the second substrate, wherein the encapsulation layer is coupled to the first substrate, the second substrate and the first integrated device.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes a substrate with a cavity and an integrated device located in the cavity of the substrate.

FIG. 2 illustrates an exemplary cross sectional profile view of an integrated device.

FIG. 3 illustrates an exemplary plan view of a package that includes a substrate with a cavity and an integrated device located in the cavity of the substrate.

FIG. 4 illustrates an exemplary cross sectional profile view of a package that includes a substrate with a cavity and an integrated device located in the cavity of the substrate.

FIG. 5 illustrates an exemplary cross sectional profile view of a package that includes a substrate with a cavity and an integrated device located in the cavity of the substrate.

FIG. 6 illustrates an exemplary cross sectional profile view of a package that includes a substrate with a cavity and an integrated device located in the cavity of the substrate.

FIGS. 7A-7E illustrate an exemplary sequence for fabricating a package that includes a substrate with a cavity and an integrated device located in the cavity of the substrate.

FIG. 8 illustrates an exemplary flow chart of a method for fabricating a package that includes a substrate with a cavity and an integrated device located in the cavity of the substrate.

FIG. 9 illustrates an exemplary sequence for fabricating a substrate with a cavity, where the substrate may include an interposer.

FIGS. 10A-10B illustrate an exemplary sequence for fabricating a substrate.

FIG. 11 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package comprising a first substrate; a first integrated device coupled to the first substrate through at least a first plurality of solder interconnects; a second substrate coupled to the first substrate through at least a second plurality of solder interconnects, wherein the second substrate includes a cavity; and an encapsulation layer located at least between the first substrate and the second substrate, wherein the encapsulation layer is coupled to the first substrate, the second substrate and the first integrated device. As will be further described below, the cavity in the second substrate, allows an integrated device with a thicker die substrate to be located in the package. The thicker die substrate of the integrated device provides better thermal conductivity than the encapsulation layer, which allows for improved heat dissipation of the integrated device and/or the package.

Exemplary Packages Comprising a Substrate with a Cavity

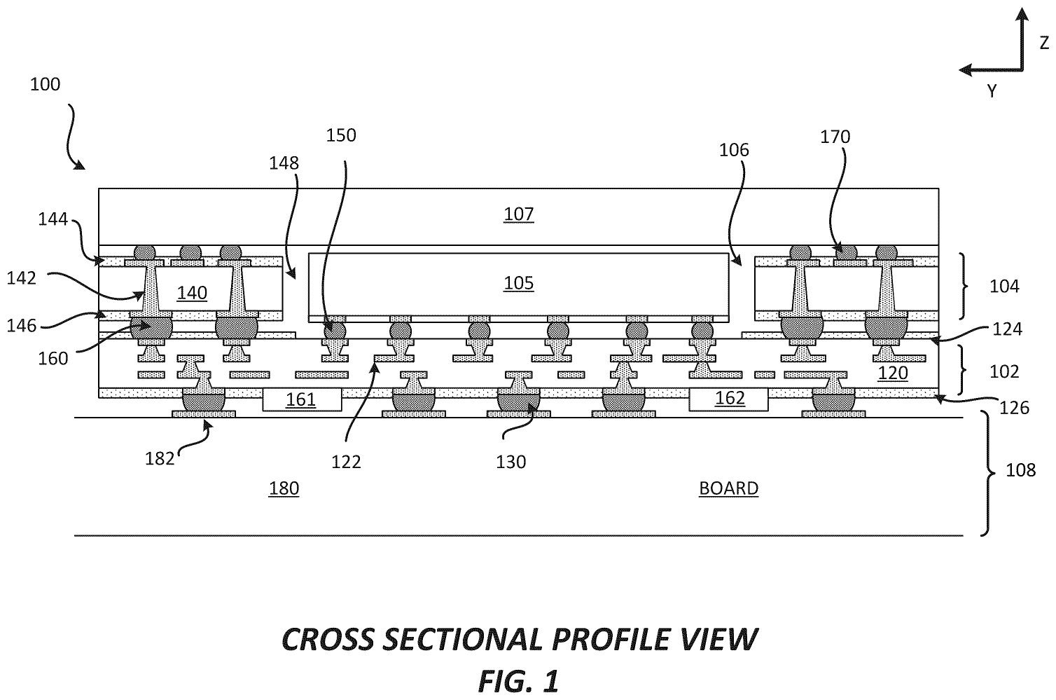

FIG. 1 illustrates a cross sectional profile view of a package 100 that includes substrate with a cavity and an integrated device located at least partially in the cavity of the substrate. The package 100 is coupled to a board 108 through a plurality of solder interconnects 130. The board 108 includes at least one board dielectric layer 180 and a plurality of board interconnects 182. The board 108 may include a printed circuit board (PCB). The package 100 is coupled to the plurality of board interconnects 182 of the board 108 through the plurality of solder interconnects 130.

The package 100 includes a substrate 102, a substrate 104, an integrated device 105 and an integrated device 107. The substrate 102 may be a first substrate. The substrate 102 includes at least one dielectric layer 120 and a plurality of interconnects 122. In some implementations, the at least one dielectric layer 120 may include prepreg and/or Ajinomoto Build-up Film (ABF). The substrate 102 may include a solder resist layer 124 and a solder resist layer 126.

The substrate 104 may be a second substrate. The substrate 104 includes at least one dielectric layer 140, a plurality of interconnects 142, a solder resist layer 144 and a solder resist layer 146. In some implementations, the at least one dielectric layer 140 may include prepreg and/or Ajinomoto Build-up Film (ABF). The solder resist layer 144 may be coupled to a first surface (e.g., top surface) of the at least one dielectric layer 140. The solder resist layer 146 may be coupled to a second surface (e.g., bottom surface) of the at least one dielectric layer 140. The substrate 104 includes a cavity 109. The cavity 109 may extend through the thickness of the substrate 104. In some implementations, as will be further described below, the substrate 104 may be an interposer (e.g., silicon interposer) with interposer interconnects.

The substrate 104 is coupled to the substrate 102 through a plurality of solder interconnects 160. The plurality of solder interconnects 160 may be coupled to and touching (i) the plurality of interconnects 122 of the substrate 102 and (ii) the plurality of interconnects 142 of the substrate 104. The integrated device 105 is coupled to the substrate 102 through a plurality of solder interconnects 150. For example, the plurality of solder interconnects 150 may be coupled to and touching (i) the plurality of interconnects 122 of the substrate 102 and the pad interconnects of the integrated device 105. In some implementations, the integrated device 105 may be coupled to the substrate 102 through a plurality of pillar interconnects (not shown) and the plurality of solder interconnects 150. The integrated device 105 is located at least partially in the cavity 148 of the substrate 104. The integrated device 105 may be laterally surrounded by the substrate 104. The substrate 104 may be configured like a ring (e.g., substrate ring, interposer ring) that laterally surrounds the integrated device 105.

In some implementations, the substrate 104 may be an interposer. The at least one dielectric layer 140 may be a silicon substrate. The plurality of interconnects 142 may include a plurality of interposer interconnects. The solder resist layer 144 may be coupled to the first surface of the silicon substrate. The solder resist layer 146 may be coupled to the second surface of the silicon substrate. The interposer may include the cavity 148.

The integrated device 107 may be coupled to the substrate 104 through a plurality of solder interconnects 170. A front side of the integrated device 107 may face a first surface (e.g., top surface) of the substrate 104 and a back side of the integrated device 105. The encapsulation layer 106 may be coupled to and touching, the substrate 102, the substrate 104, the integrated device 105 and the integrated device 107. The encapsulation layer 106 may be located at least partially in the cavity 148 of the substrate 104. The encapsulation layer 106 may be located between the integrated device 105 and the integrated device 107. The encapsulation layer 106 may be located laterally between the integrated device 105 and the substrate 104. The encapsulation layer 106 may touch the side wall of the integrated device 105 and the side wall of the cavity 148 of the substrate 104. The encapsulation layer 106 may include a mold, a resin and/or an epoxy. The encapsulation layer 106 may be a means for encapsulation. The encapsulation layer 106 may be provided by using a compression and transfer molding process, a sheet molding process, or a liquid molding process.

As will be further described below, an integrated device may include a die substrate. The die substrate may include silicon. However, the die substrate may include other materials. Silicon may have a thermal conductivity of about 148 Watts per meter Kelvin (W/m-K). In contrast, the encapsulation layer 106 may have a thermal conductivity of 0.9 Watts per meter Kelvin (W/m-K). The higher thermal conductivity of silicon relative to the thermal conductivity of the encapsulation layer 106 means using a thicker die substrate will lead to improve heat dissipation of the integrated device 105. Thus, in some implementations, the integrated device 105 may be optimized for heat dissipation by increasing and/or maximizing the thickness of the die substrate of the integrated device 105. However, such increase in the thickness of the die substrate of the integrated device 105 may not necessarily increase the overall thickness of the package, due to the presence and use of the cavity 148 in the substrate 104. As mentioned above, it is noted that the die substrate may include a different material from silicon, such as GaAs, which may have a different thermal conductivity from silicon.

In some implementations, the substrate 102 may include a thickness in a range of about 100-300 micrometers. In some implementations, the substrate 104 may include a thickness in a range of about 50-150 micrometers. In some implementations, the encapsulation layer between the substrate 102 and the substrate 104, may include a thickness in a range of about 100-300 micrometers. However, the above dimensions are merely exemplary. Different implementations may have different dimensions and/or thicknesses.

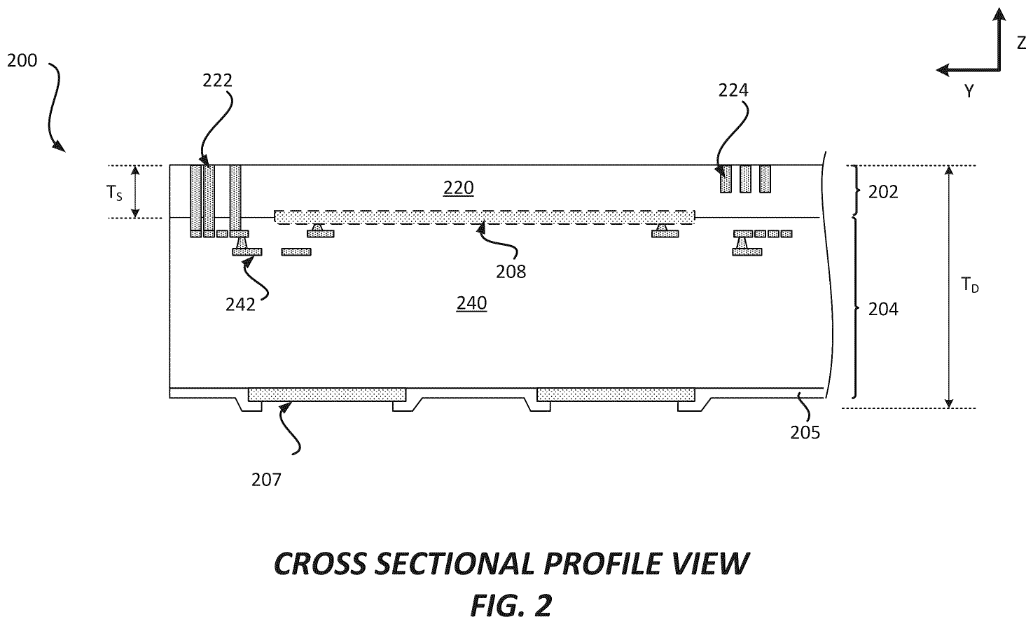

FIG. 2 illustrates an exemplary profile view of the integrated device 200. The integrated device 200 may represent the integrated device 105 of FIG. 1. The integrated device 200 includes a die substrate portion 202 and a die interconnection portion 204. The die substrate portion 202 includes a die substrate 220 and an active region 208. The active region 208 may include a plurality of logic cells, a plurality of transistors, and/or a plurality of filters. Different implementations may use different types of transistors, such as a field effect transistor (FET), planar FET, finFET, and a gate all around FET. In some implementations, a front end of line (FEOL) process may be used to fabricate the active region 208 of the die substrate 220. The die substrate 220 may include silicon. In some implementations, the die substrate 220 that includes silicon may have a thermal conductivity of about 148 Watts per meter Kelvin (W/m-K). In some implementations, the integrated device 200 may have a thickness (T_{D}) in a range of about 40-800 micrometers. In some implementations, the die substrate 220 may have a thickness (T_{S}) in a range of about 32-792 micrometers. In some implementations, the die interconnection portion 204 may have a thickness that is about 8 micrometers or greater. However, it should be noted that the above dimensions are exemplary and different implementations may have different thicknesses.

The die interconnection portion 204 includes at least one dielectric layer 240 and a plurality of die interconnects 242. The die interconnection portion 204 is coupled to the die substrate portion 202. The plurality of die interconnects 242 are coupled to the active region 208 of the die substrate portion 202. The die interconnection portion 204 may also include a plurality of pad interconnects 207 and a passivation layer 205. In some implementations, a back end of line (BEOL) process may be used to fabricate the die interconnection portion 204. The plurality of solder interconnects 150 may be coupled to the plurality of pad interconnects 207. The integrated device 200 may have a thickness (T_{D}) in a range of about 40-800 micrometers. A front side of the integrated device 200 may include the side that includes the plurality of pad interconnects 207 and/or the passivation layer 205. A back side of the integrated device 200 may include the side that includes the die interconnection portion 204 and/or the die substrate 220. Although not shown, an integrated device 200 may include a back side metallization portion. The back side metallization may include at least one dielectric layer (not shown) and a plurality of metallization interconnects (not shown). The die substrate 220 may include a plurality of through substrate vias 222 that are coupled to the plurality of die interconnects 242.

In some implementations, to further increase the heat dissipation capabilities of the integrated device, a plurality of through substrate vias 224 may be located in the die substrate 220. The plurality of through substrate vias 224 may include a plurality of dummy through substrate vias. A dummy through substrate via may be a through substrate via that is configured to not be electrically coupled to active components and/or active regions of the integrated device. A dummy through substrate via may include a metal (e.g., copper), which has thermal conductivity that is much higher than the die substrate 220 and/or the encapsulation layer 106. For example, when a dummy through substrate via includes copper, the dummy through substrate via may have a thermal conductivity of about 385 Watts per meter Kelvin (W/m-K).

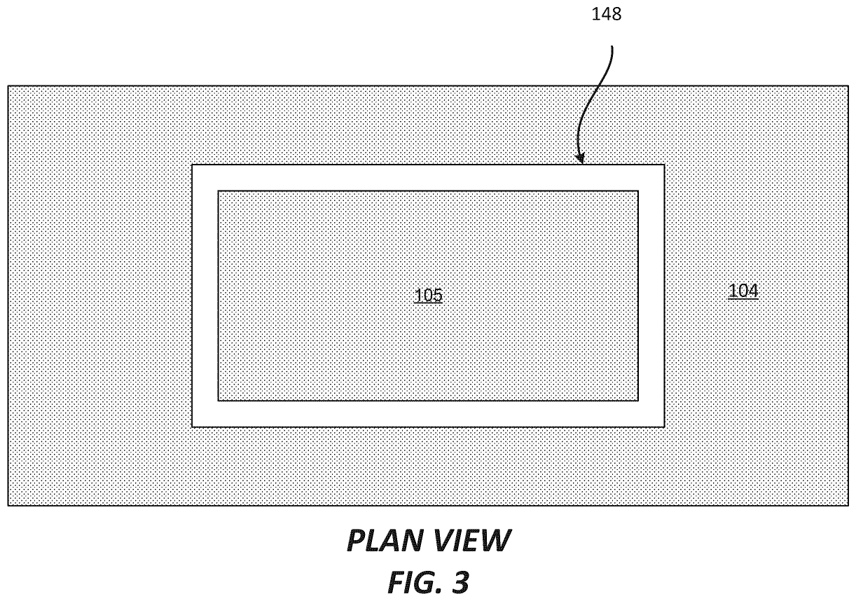

FIG. 3 illustrates a plan view of the package 100 that includes the substrate 104 and the integrated device 105. The substrate 104 includes a cavity 148. The integrated device 105 is located at least partially in the cavity 148 of the substrate 104. The encapsulation layer 106 may be located laterally between the integrated device 105 and the substrate 104.

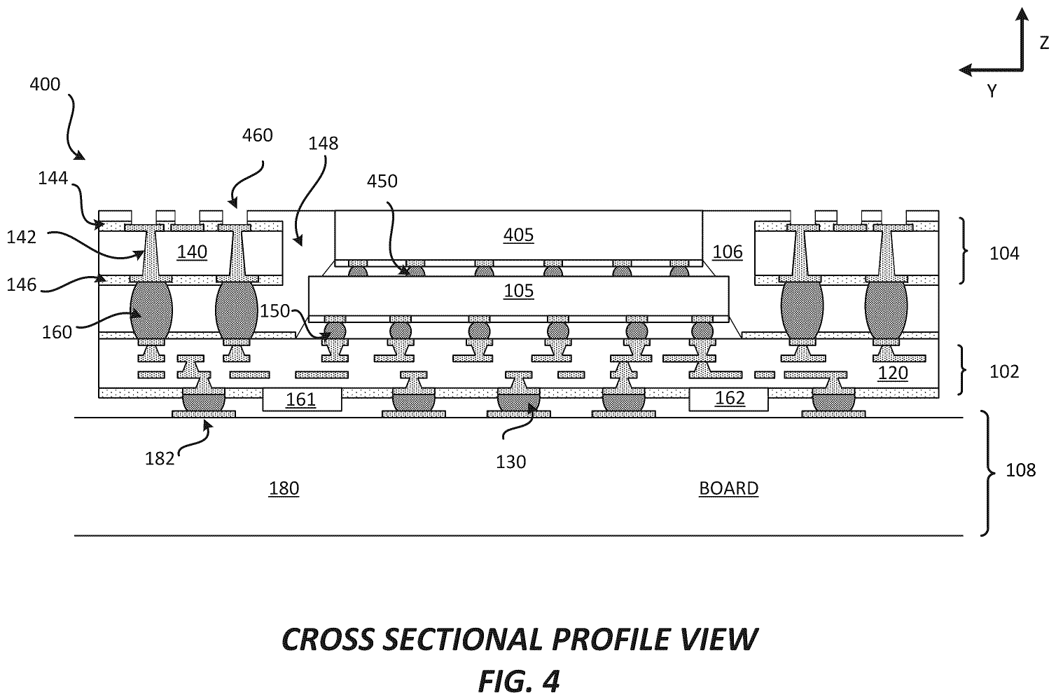

FIG. 4 illustrates a cross sectional profile view of a package 400 that includes substrate with a cavity and an integrated device located at least partially in the cavity of the substrate. The package 400 is coupled to a board 108 through a plurality of solder interconnects 130.

The package 400 is similar to the package 100 of FIG. 1, and may include similar and/or the same components that are arranged in a similar manner. The package 400 includes a substrate 102, a substrate 104, an integrated device 105 and an integrated device 405. The substrate 102 may be a first substrate. The substrate 104 may be a second substrate. The package 400 also includes a passive component 161 and a passive component 162. The passive component 161 and/or the passive component 162 may be coupled to a bottom surface of the substrate 102 (e.g., through a plurality of solder interconnects).

The substrate 104 is coupled to the substrate 102 through the plurality of solder interconnects 160. The integrated device 105 is coupled to the substrate 102 through the plurality of solder interconnects 150. The encapsulation layer 106 may be located between the substrate 102 and the integrated device 105. In some implementations, an underfill may be located between the substrate 102 and the integrated device 105. The integrated device 107 is coupled to the integrated device 105 through the plurality of solder interconnects 450. The front side of the integrated device 405 may face the back side of the integrated device 105.

In some implementations, an electrical path between the integrated device 405 and the integrated device 105 may include a solder interconnect from the plurality of solder interconnects 450, a metallization interconnect from the plurality of metallization interconnects of the integrated device 105, a through substrate via from the plurality of through substrate vias 222 of the integrated device 105 and/or a die interconnect from the plurality of die interconnects 242.

In some implementations, the encapsulation layer 106 may be located between the integrated device 105 and the integrated device 405. The integrated device 405 may be similar to the integrated device 200. In some implementations, an underfill may be located between the integrated device 105 and the integrated device 405. An underfill may include a different material from the encapsulation layer 106.

The integrated device 105 and/or the integrated device 405 may be located at least partially in the cavity 148 of the substrate 104. In some implementations, the integrated device 105 is located at least partially in the cavity 148 of the substrate 104. In some implementations, the integrated device 405 is located at least partially in the cavity 148 of the substrate 104. The integrated device 105 and the integrated device 405 may be located at least partially in the cavity 148 of the substrate 104. The encapsulation layer 106 may be located at least partially in the cavity 148 of the substrate 104.

The encapsulation layer 106 is coupled to the substrate 102, the substrate 104, the integrated device 105 and the integrated device 405. The encapsulation layer 106 may be located between the substrate 102 and the substrate 104. The encapsulation layer 106 may at least partially surround and/or encapsulate the integrated device 105 and/or the integrated device 405. The encapsulation layer 106 may laterally surround the integrated device 105 and/or the integrated device 405. The encapsulation layer 106 may be located laterally between the integrated device 105 and the substrate 104. The encapsulation layer 106 may be located laterally between the integrated device 405 and the substrate 104. The encapsulation layer 106 may be located over the substrate 104.

A plurality of openings 460 may be located in the encapsulation layer 106. The plurality of openings 460 may extend through the encapsulation layer 106 and the solder resist layer 144 of the substrate 104. The plurality of openings 460 may expose pad interconnects from the plurality of interconnects 142. The plurality of pad interconnects may be used as landing pads for a plurality of solder interconnects.

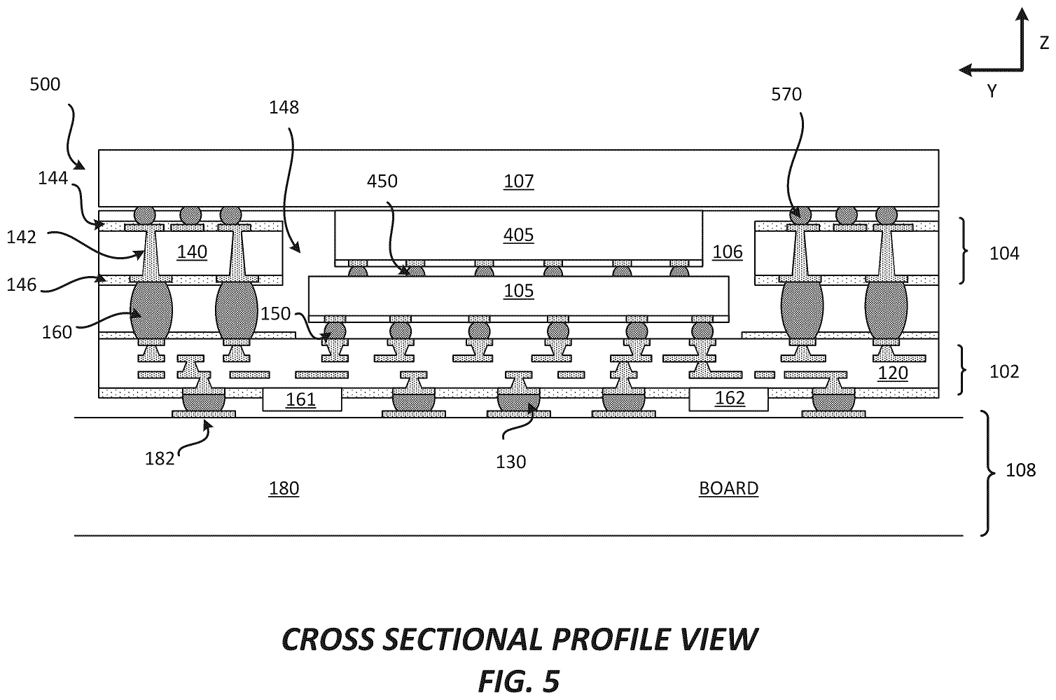

FIG. 5 illustrates a cross sectional profile view of a package 500 that includes substrate with a cavity and an integrated device located at least partially in the cavity of the substrate. The package 400 is coupled to a board 108 through a plurality of solder interconnects 130.

The package 500 is similar to the package 400 of FIG. 4, and may include similar and/or the same components that are arranged in a similar manner. The package 500 includes a substrate 102, a substrate 104, an integrated device 105, an integrated device 405 and an integrated device 107. The integrated device 107 is coupled to the substrate 104 through a plurality of solder interconnects 570. The plurality of solder interconnects 570 may be coupled to the plurality of pad interconnects from the plurality of interconnects 142. The plurality of solder interconnects 570 may located at least partially in the plurality of openings 460. A front side of the integrated device 107 may face a back side of the integrated device 405.

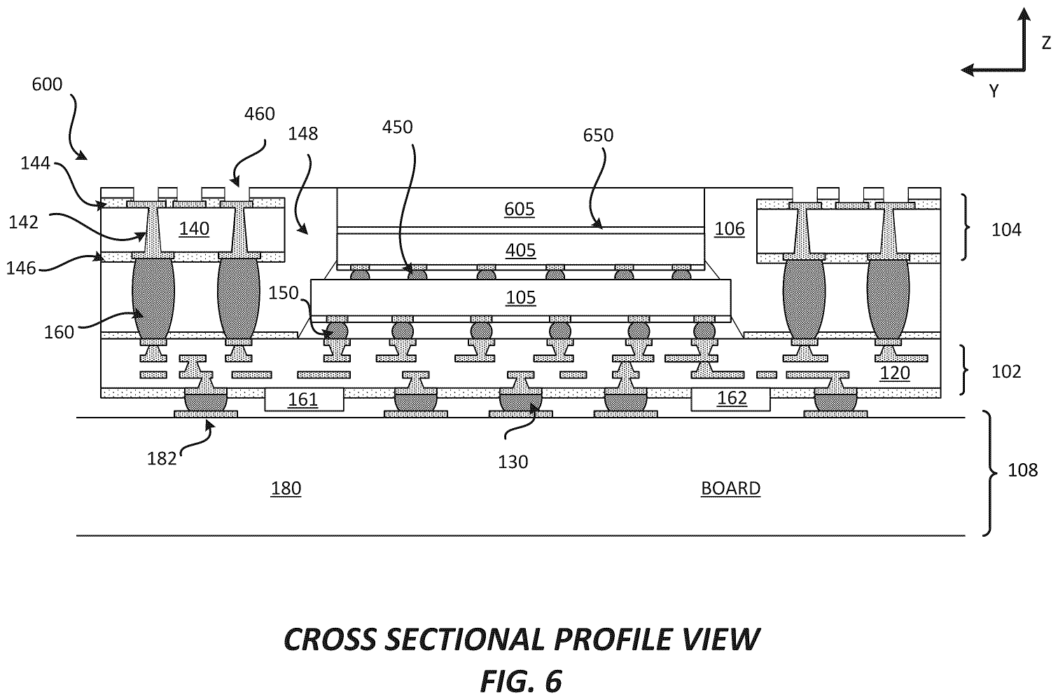

FIG. 6 illustrates a cross sectional profile view of a package 600 that includes substrate with a cavity and an integrated device located at least partially in the cavity of the substrate. The package 600 is coupled to a board 108 through a plurality of solder interconnects 130.

The package 600 is similar to the package 400 of FIG. 4, and may include similar and/or the same components that are arranged in a similar manner. The package 600 includes a substrate 102, a substrate 104, an integrated device 105, an integrated device 405 and a heat sink 605. The substrate 102 may be a first substrate. The substrate 104 may be a second substrate. The package 400 also includes a passive component 161 and a passive component 162. The passive component 161 and/or the passive component 162 may be coupled to a bottom surface of the substrate 102 (e.g., through a plurality of solder interconnects).

The substrate 104 is coupled to the substrate 102 through the plurality of solder interconnects 160. The integrated device 105 is coupled to the substrate 102 through the plurality of solder interconnects 150. The encapsulation layer 106 may be located between the substrate 102 and the integrated device 105. In some implementations, an underfill may be located between the substrate 102 and the integrated device 105. The integrated device 405 is coupled to the integrated device 105 through the plurality of solder interconnects 450. The front side of the integrated device 405 may face the back side of the integrated device 105.

The heat sink 605 is coupled to a back side of the integrated device 405 through a thermal interface material 650. The heat sink 605 may include a metal. The heat sink 605 may include a material with a high thermal conductivity (e.g., higher thermal conductivity than the thermal conductivity of silicon and/or an encapsulation layer). The heat sink 605 may help dissipate heat from the integrated device 405. The encapsulation layer 106 may be located between the integrated device 105 and the integrated device 405. The integrated device 405 may be similar to the integrated device 200. In some implementations, an underfill may be located between the integrated device 105 and the integrated device 405. An underfill may include a different material from the encapsulation layer 106.

The integrated device 105, the integrated device 405 and/or the heat sink 605 may be located at least partially in the cavity 148 of the substrate 104. In some implementations, the integrated device 105 is located at least partially in the cavity 148 of the substrate 104. In some implementations, the integrated device 405 is located at least partially in the cavity 148 of the substrate 104. In some implementations, the heat sink 605 is located at least partially in the cavity 148 of the substrate 104. The heat sink 605 and the integrated device 405 may be located at least partially in the cavity 148 of the substrate 104. The encapsulation layer 106 may be located at least partially in the cavity 148 of the substrate 104.

The encapsulation layer 106 is coupled to the substrate 102, the substrate 104, the integrated device 105, the integrated device 405 and the heat sink 605. The encapsulation layer 106 may be located between the substrate 102 and the substrate 104. The encapsulation layer 106 may at least partially surround and/or encapsulate the integrated device 105, the integrated device 405 and/or the heat sink 605. The encapsulation layer 106 may laterally surround the integrated device 105, the integrated device 405 and/or the heat sink 605. The encapsulation layer 106 may be located laterally between the integrated device 105 and the substrate 104. The encapsulation layer 106 may be located laterally between the integrated device 405 and the substrate 104. The encapsulation layer 106 may be located laterally between the heat sink 605 and the substrate 104. The encapsulation layer 106 may be located over the substrate 104.

It is noted that the substrate 104 may be considered to have a cavity 148, even if the cavity is filled and/or occupied by other material and/or components, such as the encapsulation layer 106, the integrated device 105, the integrated device 405 and/or the heat sink 605.

A plurality of openings 460 may be located in the encapsulation layer 106. The plurality of openings 460 may extend through the encapsulation layer 106 and the solder resist layer 144 of the substrate 104. The plurality of openings 460 may expose pad interconnects from the plurality of interconnects 142. The plurality of pad interconnects may be used as landing pads for a plurality of solder interconnects.

In some implementations, an integrated device 107 may be coupled to the substrate 104 of the package 600 in a similar manner as how the integrated device 107 of FIG. 5, may be coupled to the substrate 104 of the package 500.

An integrated device (e.g., 105, 107, 405) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 100) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package may be implemented in a radio frequency (RF) package. The RF package may be a radio frequency front end (RFFE) package. A package (e.g., 100) may be configured to provide Wireless Fidelity (WiFi) communication and/or cellular communication (e.g., 2G, 3G, 4G, 5G, 6G). The packages (e.g., 100) may be configured to support Global System for Mobile (GSM) Communications, Universal Mobile Telecommunications System (UMTS), and/or Long-Term Evolution (LTE). The packages may be configured to transmit and receive signals having different frequencies and/or communication protocols.

Exemplary Sequence for Fabricating a Package Comprising a Substrate with a Cavity

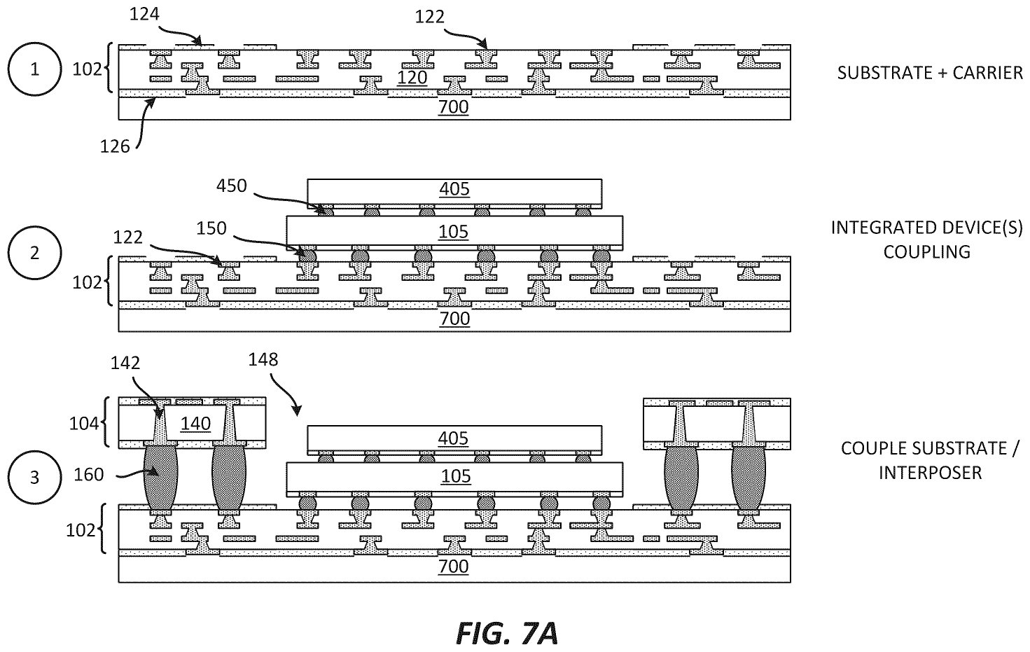

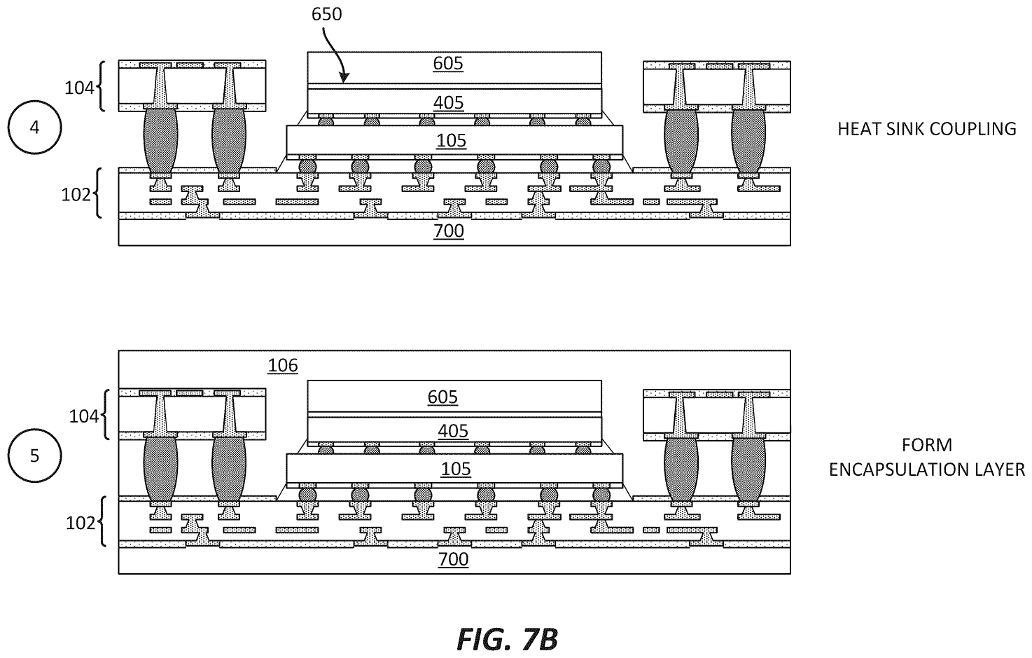

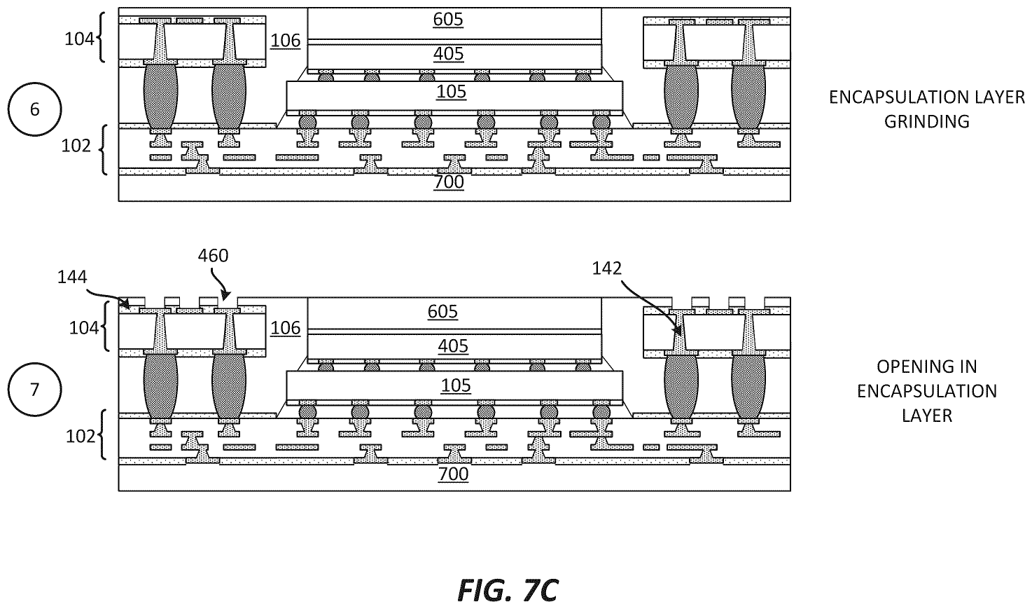

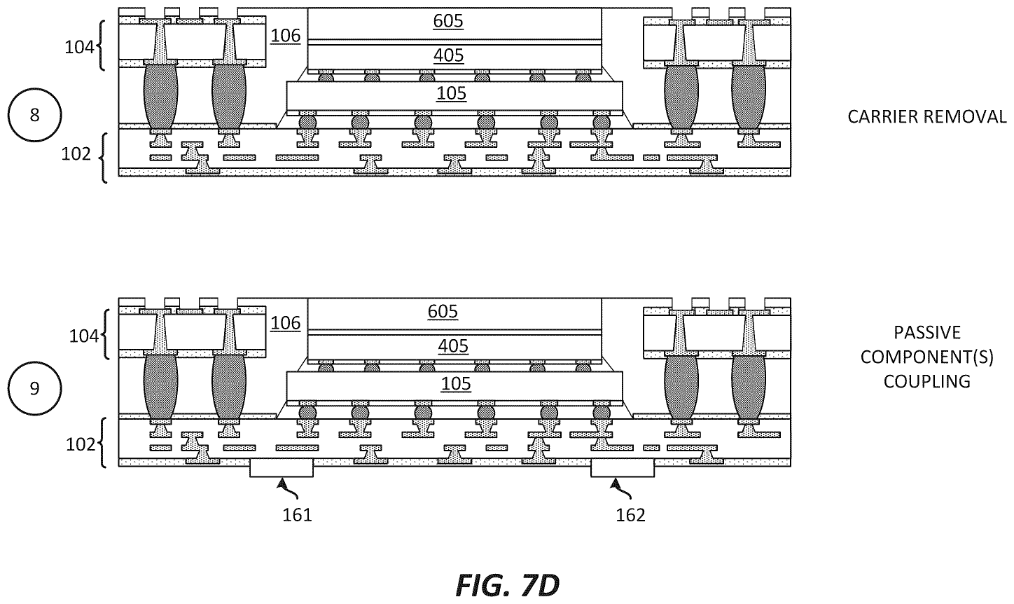

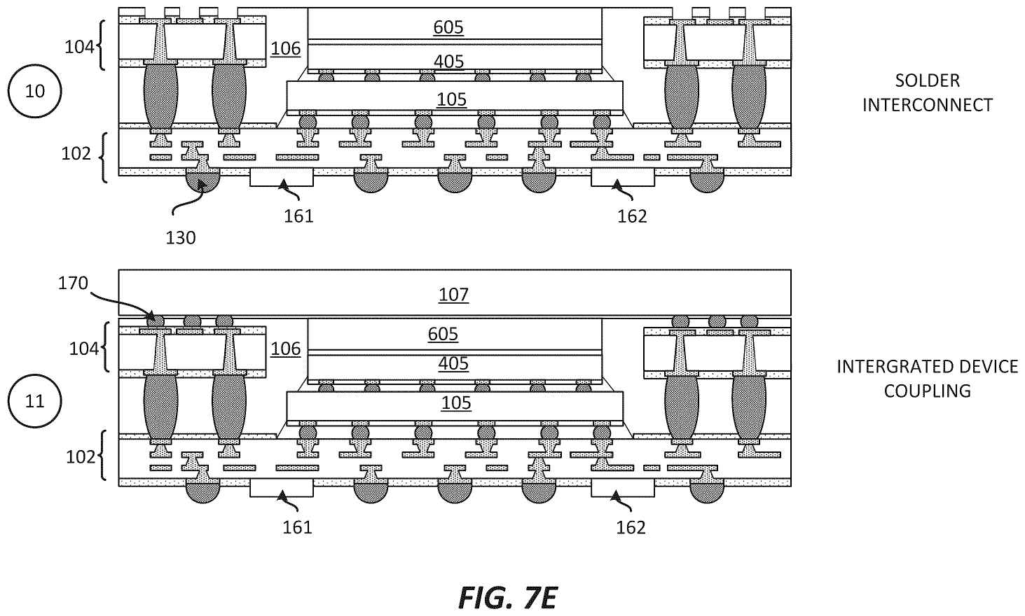

In some implementations, fabricating a package includes several processes. FIGS. 7A-7E illustrate an exemplary sequence for providing or fabricating a package. In some implementations, the sequence of FIGS. 7A-7E may be used to provide or fabricate the package 600. However, the process of FIGS. 7A-7E may be used to fabricate any of the packages described in the disclosure.

It should be noted that the sequence of FIGS. 7A-7E may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.
Stage 1, as shown in FIG. 7A, illustrates a state after a substrate 102 and a carrier 700 are provided. The substrate 102 may be a first substrate. The substrate 102 includes at least one dielectric layer 120, a plurality of interconnects 122, a solder resist layer 124 and a solder resist layer 126. The substrate 102 is coupled to the carrier 700.
Stage 2 illustrates a state after an integrated device 105 is coupled to the substrate 102 through a plurality of solder interconnects 150. The integrated device 405 may be coupled to the integrated device 105 through a plurality of solder interconnects 450. A solder reflow process may be used to couple the integrated device 405 to the integrated device 105 through the plurality of solder interconnects 450, and to couple the integrated device 105 to the substrate 102 through the plurality of solder interconnects 150. Other integrated devices and/or components may be coupled to the substrate 102.
Stage 3 illustrates a state after the substrate 104 is coupled to the substrate 102 through a plurality of solder interconnects 160. A solder reflow process may be used to couple the substrate 104 is coupled to the substrate 102 through a plurality of solder interconnects 160. The substrate 104 may be a second substrate. The substrate 104 includes at least one dielectric layer 140, a plurality of interconnects 142, a solder resist layer 144 and a solder resist layer 146. The substrate 104 also includes a cavity 148. The integrated device 105 and/or the integrated device 405 may be at least partially in the cavity 148 of the substrate 104. In some implementations, the integrated device 105 and/or the integrated device 405 may be located below the cavity 148 of the substrate 104. In some implementations, the integrated device 105 and/or the integrated device 405 may be located between the cavity 148 of the substrate 104 and the substrate 102. The substrate 104 may include an interposer. The at least one dielectric layer 140 may include a silicon substrate. The plurality of interconnects 142 may include a plurality of interposer interconnects.
Stage 4, as shown in FIG. 7B, illustrates a state after a heat sink 605 is coupled to the integrated device 405 through a thermal interface material 650. The heat sink 605 may be coupled to a back side of the integrated device 405 through the thermal interface material 650.
Stage 5, illustrates a state after an encapsulation layer 106 is formed and/or provided. The encapsulation layer 106 may be coupled to the substrate 102, the substrate 104, the integrated device 105, the integrated device 405, and the heat sink 605. The encapsulation layer 106 may at least partially encapsulate the integrated device 105, the integrated device 405 and the heat sink 605. The encapsulation layer 106 may be located at least partially in the cavity 148 of the substrate 104. The encapsulation layer 106 may be located between the substrate 102 and the substrate 104. The encapsulation layer 106 may be located over the substrate 104 and the heat sink 605.
Stage 6, as shown in FIG. 7C, illustrates a state after a portion of the encapsulation layer 106 is removed. A grinding process may be used to thin a portion of the encapsulation layer 106. In some implementations, the encapsulation layer 106 is thinned and exposes part of a surface of the heat sink 605.
Stage 7, illustrates a state after a plurality of openings 460 are formed in the encapsulation layer 106 and the solder resist layer 144 to expose pad interconnects from the plurality of interconnects 142 of the substrate 104. A laser process may be used to form a plurality of openings 460 in the encapsulation layer 106 and the solder resist layer 144. The plurality of openings 460 may extend through the encapsulation layer 106 and the solder resist layer 144.
Stage 8, as shown in FIG. 7D, illustrates a state after the carrier 700 is removed. The carrier 700 may be decoupled from the substrate 102. The carrier 700 may be detached and/or peeled off from the substrate 102.
Stage 9, illustrates a state after a passive component 161 and/or a passive component 162 are coupled to a bottom surface (e.g., second surface) of the substrate 102. The passive component 161 and/or the passive component 162 may be coupled to the plurality of interconnects 122 of the substrate 102 through a plurality of solder interconnects (not shown).
Stage 10, as shown in FIG. 7E, illustrates a state after a plurality of solder interconnects 130 are coupled to the substrate 102. A solder reflow process may be used to couple the plurality of solder interconnects 130 to a second surface (e.g., bottom surface) of the substrate 102.
Stage 11, illustrates a state after an integrated device 107 is coupled to the substrate 104 through a plurality of solder interconnects 170. A solder reflow process may be used to couple the integrated device 107 to the substrate 104 through the plurality of solder interconnects 170. The plurality of solder interconnects 170 may be coupled to the plurality of interconnects 142 and pad interconnects (e.g., 207) of the integrated device 107. The plurality of solder interconnects 170 may be located at least partially in the plurality of openings 460 of the encapsulation layer 106 and the solder resist layer 144. Stage 11 may illustrate a package 600 that includes a substrate 102, a substrate 104 with a cavity 148, an encapsulation layer 106, an integrated device 105, the integrated device 405, the heat sink 605 and the integrated device 107. The substrate 104 may be considered to have a cavity 148 that is at least partially occupied by the integrated device 105, the integrated device 405, the heat sink 605 and/or the encapsulation layer 106.
   Exemplary Flow Diagram of a Method for Fabricating a Package Comprising a Substrate with a Cavity

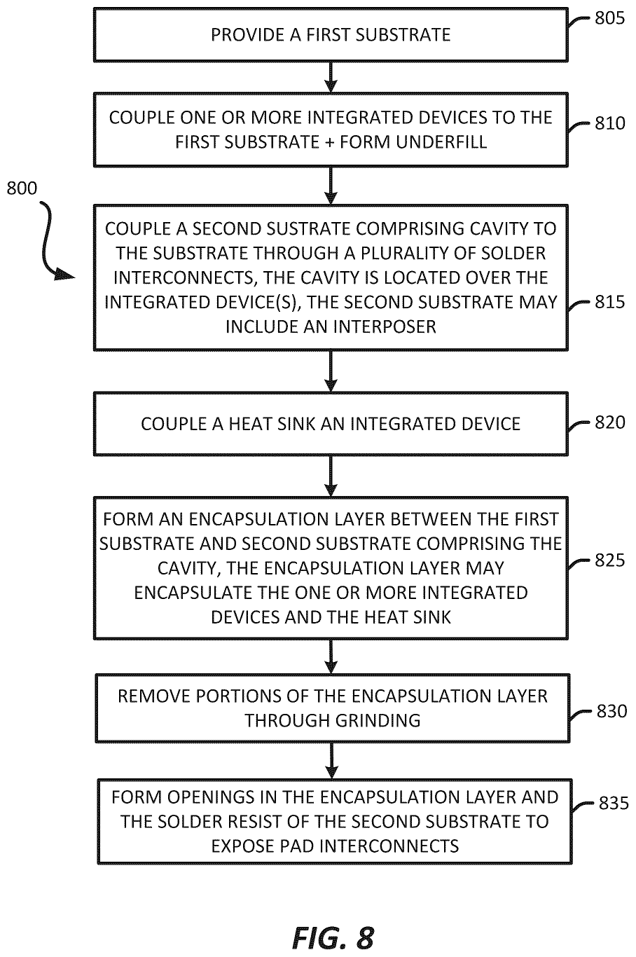

In some implementations, fabricating a package includes several processes. FIG. 8 illustrates an exemplary flow diagram of a method 800 for providing or fabricating a package. In some implementations, the method 800 of FIG. 8 may be used to provide or fabricate the package 600 described in the disclosure. However, the method 800 may be used to provide or fabricate any of the packages described in the disclosure.

It should be noted that the method 800 of FIG. 8 may combine one or more processes in order to simplify and/or clarify the method for providing or fabricating a package. In some implementations, the order of the processes may be changed or modified.

The method provides (at 805) a first substrate. In some implementations, the first substrate is provided with a carrier. The first substrate may be coupled to a carrier. Stage 1 of FIG. 7A, illustrates and describes an example of a state after a substrate 102 and a carrier 700 are provided. The substrate 102 may be a first substrate. The substrate 102 includes at least one dielectric layer 120, a plurality of interconnects 122, a solder resist layer 124 and a solder resist layer 126. The substrate 102 is coupled to the carrier 700.

The method couples (at 810) one or more integrated devices to the first substrate through a plurality of solder interconnects. Stage 2 of FIG. 7A, illustrates and describes an example of a state after an integrated device 105 is coupled to the substrate 102 through a plurality of solder interconnects 150. The integrated device 405 may be coupled to the integrated device 105 through a plurality of solder interconnects 450. A solder reflow process may be used to couple the integrated device 405 to the integrated device 105 through the plurality of solder interconnects 450, and to couple the integrated device 105 to the substrate 102 through the plurality of solder interconnects 150. Other integrated devices and/or components may be coupled to the substrate 102. In some implementations, an underfill may be provided and/or formed between an integrated device and the substrate 102.

The method couples (at 815) a second substrate comprising a cavity, to the first substrate through a plurality of solder interconnects. Stage 3 of FIG. 7A, illustrates and describes an example of a state after the substrate 104 is coupled to the substrate 102 through a plurality of solder interconnects 160. A solder reflow process may be used to couple the substrate 104 is coupled to the substrate 102 through a plurality of solder interconnects 160. The substrate 104 may be a second substrate. The substrate 104 includes at least one dielectric layer 140, a plurality of interconnects 142, a solder resist layer 144 and a solder resist layer 146. The substrate 104 also includes a cavity 148. The integrated device 105 and/or the integrated device 405 may be at least partially in the cavity 148 of the substrate 104. In some implementations, the integrated device 105 and/or the integrated device 405 may be located below the cavity 148 of the substrate 104. In some implementations, the integrated device 105 and/or the integrated device 405 may be located between the cavity 148 of the substrate 104 and the substrate 102. The substrate 104 may include an interposer. The at least one dielectric layer 140 may include a silicon substrate. The plurality of interconnects 142 may include a plurality of interposer interconnects.

The method couples (at 820) a heat sink to one or more integrated devices. Stage 4 of FIG. 7B, illustrates and describes an example of a state after a heat sink 605 is coupled to the integrated device 405 through a thermal interface material 650. The heat sink 605 may be coupled to a back side of the integrated device 405 through the thermal interface material 650.

The method forms (at 825) an encapsulation layer that is coupled to the first substrate, the second substrate and integrated devices. The encapsulation layer may also be coupled to a heat sink. Stage 5 of FIG. 7B, illustrates and describes an example of a state after an encapsulation layer 106 is formed and/or provided. The encapsulation layer 106 may be coupled to the substrate 102, the substrate 104, the integrated device 105, the integrated device 405, and the heat sink 605. The encapsulation layer 106 may at least partially encapsulate the integrated device 105, the integrated device 405 and the heat sink 605. The encapsulation layer 106 may be located at least partially in the cavity 148 of the substrate 104. The encapsulation layer 106 may be located between the substrate 102 and the substrate 104. The encapsulation layer 106 may be located over the substrate 104 and the heat sink 605.

The method removes (at 830) portions of the encapsulation layer. Removing portions of the encapsulation layer may include thinning the encapsulation layer. A grinding process may be used to thin the encapsulation layer. Stage 6 of FIG. 7C, illustrates and describes an example of a state after a portion of the encapsulation layer 106 is removed. A grinding process may be used to thin a portion of the encapsulation layer 106. In some implementations, the encapsulation layer 106 is thinned and exposes part of a surface of the heat sink 605.

The method forms (at 835) a plurality of openings in an encapsulation layer and a solder resist layer. Stage 7 of FIG. 7C, illustrates and describes an example of a state after a plurality of openings 460 are formed in the encapsulation layer 106 and the solder resist layer 144 to expose pad interconnects from the plurality of interconnects 142 of the substrate 104. A laser process may be used to form a plurality of openings 460 in the encapsulation layer 106 and the solder resist layer 144. The plurality of openings 460 may extend through the encapsulation layer 106 and the solder resist layer 144.

If and/or when a carrier is provided, the method 800 after forming the plurality of openings, may decouple the carrier from the first substrate. Stage 8 of FIG. 7D, illustrates and describes an example of a state after the carrier 700 is removed. The carrier 700 may be decoupled from the substrate 102. The carrier 700 may be detached and/or peeled off from the substrate 102.

Additional processes may be performed to fabricate a package. In some implementations, the method 800 may couple one or more passive components to the first substrate. Stage 9 of FIG. 7D, illustrates and describes an example of a state after a passive component 161 and/or a passive component 162 are coupled to a bottom surface (e.g., second surface) of the substrate 102. The passive component 161 and/or the passive component 162 may be coupled to the plurality of interconnects 122 of the substrate 102 through a plurality of solder interconnects (not shown).

The method 800 may couple a plurality of solder interconnects to the first substrate. Stage 10 of FIG. 7E, illustrates and describes an example of a state after a plurality of solder interconnects 130 are coupled to the substrate 102. A solder reflow process may be used to couple the plurality of solder interconnects 130 to a second surface (e.g., bottom surface) of the substrate 102.

In some implementations, additional integrated devices may be coupled to the package. Stage 11 of FIG. 7E, illustrates and describes an example of a state after an integrated device 107 is coupled to the substrate 104 through a plurality of solder interconnects 170. A solder reflow process may be used to couple the integrated device 107 to the substrate 104 through the plurality of solder interconnects 170. The plurality of solder interconnects 170 may be coupled to the plurality of interconnects 142 and pad interconnects (e.g., 207) of the integrated device 107. The plurality of solder interconnects 170 may be located at least partially in the plurality of openings 460 of the encapsulation layer 106 and the solder resist layer 144. Stage 11 of FIG. 7E, may illustrate a package 600 that includes a substrate 102, a substrate 104 with a cavity 148, an encapsulation layer 106, an integrated device 105, the integrated device 405, the heat sink 605 and the integrated device 107. The substrate 104 may be considered to have a cavity 148 that is at least partially occupied by the integrated device 105, the integrated device 405, the heat sink 605 and/or the encapsulation layer 106.

Exemplary Sequence for Fabricating a Package Comprising a Substrate with a Cavity

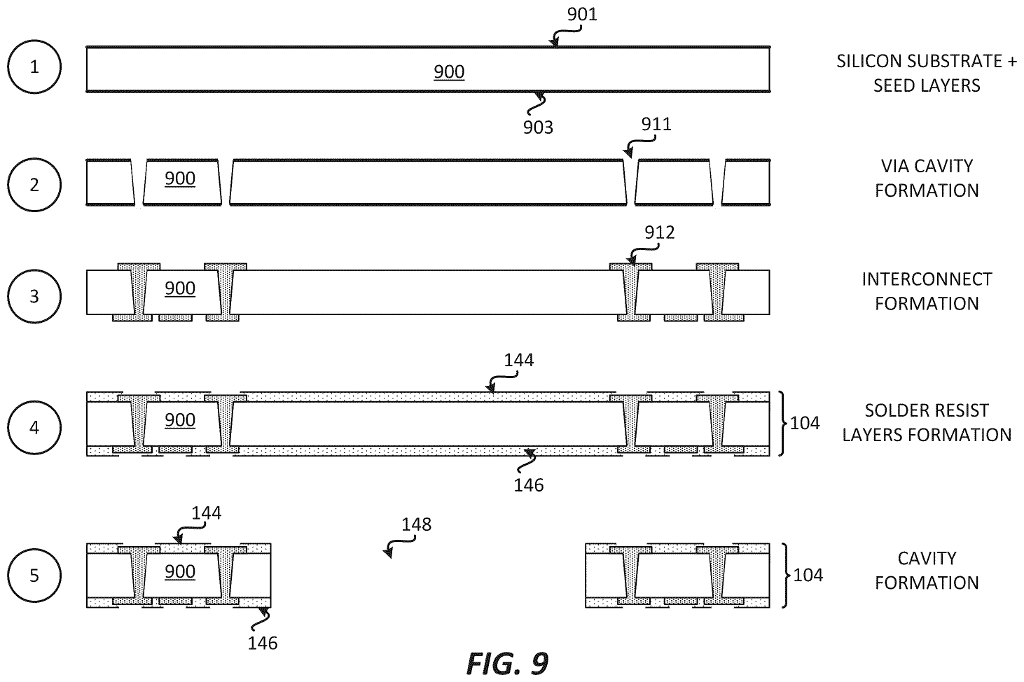

In some implementations, fabricating a package includes several processes. FIG. 9 illustrates an exemplary sequence for providing or fabricating a substrate. In some implementations, the sequence of FIG. 9 may be used to provide or fabricate the substrate 104. However, the process of FIG. 9 may be used to fabricate any of the substrates described in the disclosure.

It should be noted that the sequence of FIG. 9 may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.
Stage 1, as shown in FIG. 9, illustrates a state after a silicon substrate 900. A seed layer 901 and a seed layer 903 may be coupled to the silicon substrate 900. The seed layer 901 and/or the seed layer 903 may include copper.
Stage 2 illustrates a state after a plurality of cavities 911 are formed in the silicon substrate 900. A laser process (e.g., laser ablation) may be used to form the plurality of cavities 911 through the seed layer 901, the silicon substrate 900 and the seed layer 903.
Stage 3 illustrates a state after a plurality of interconnects 912 are formed. The plurality of interconnects 912 in the plurality of cavities 911. The plurality of interconnects 912 may be coupled to the seed layer 901 and the seed layer 903. A plating process may be used to form the plurality of interconnects 912. An etching process may be used to selectively remove the seed layer 901 and/or the seed layer 903.
Stage 4 illustrates a state after a solder resist layer 144 and a solder resist layer 146 are formed. The solder resist layer 144 is formed and coupled to a first surface of the silicon substrate 900. The solder resist layer 144 may include a plurality of openings. The solder resist layer 146 is formed and coupled to a second surface of the silicon substrate 900. The solder resist layer 146 may include a plurality of openings.
Stage 5 illustrates a state after a cavity 148 is formed through the solder resist layer 144, the silicon substrate 900 and the solder resist layer 146. A laser process (e.g., laser ablation) may be used to form the cavity 148. Stage 5 may illustrate a substrate 104 that includes the cavity 148. The silicon substrate 900 may be an example of the at least one dielectric layer 140. The plurality of interconnects 912 may represent the plurality of interconnects 142.

### Exemplary Sequence for Fabricating a Substrate

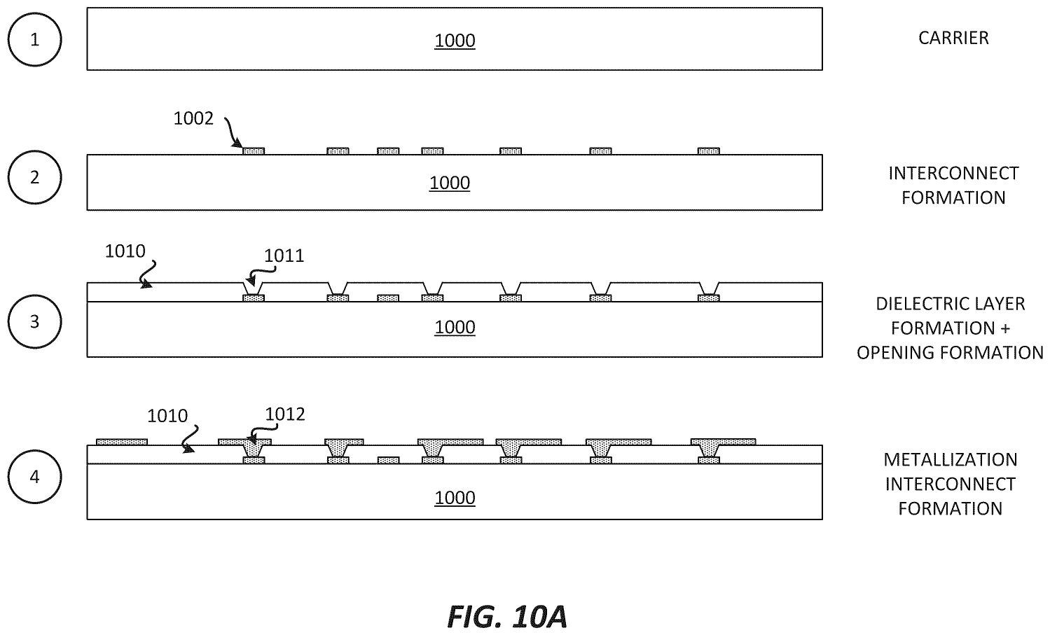

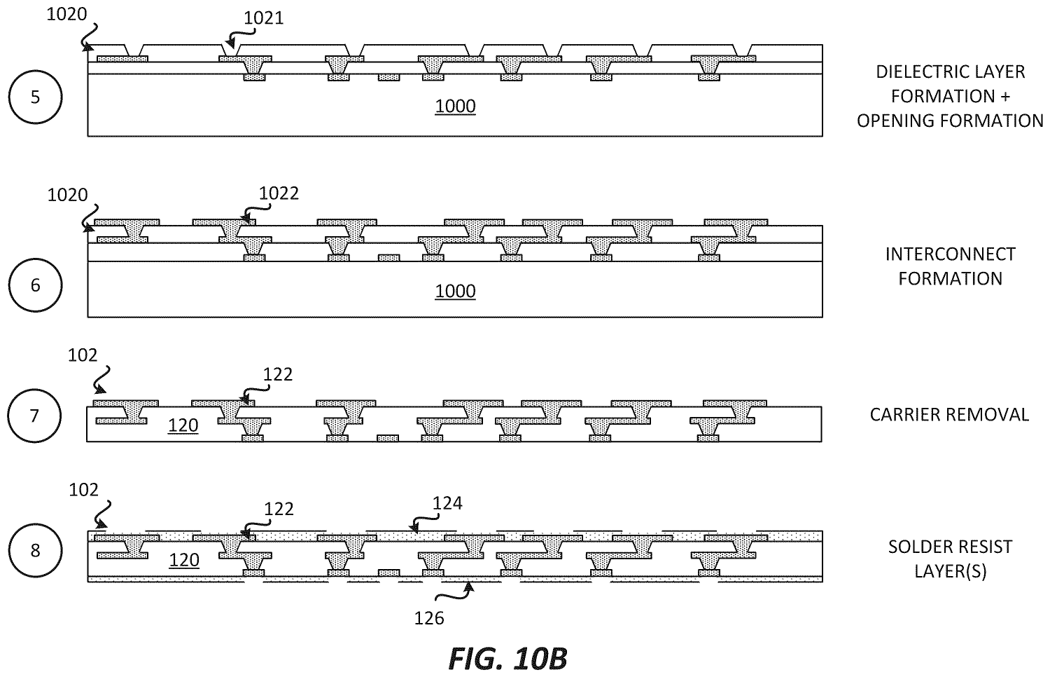

In some implementations, fabricating a substrate includes several processes. FIGS. 10A-10B illustrate an exemplary sequence for providing or fabricating a substrate. In some implementations, the sequence of FIGS. 10A-10B may be used to provide or fabricate the substrate 102. However, the process of FIGS. 10A-10B may be used to fabricate any of the substrates (e.g., 104) described in the disclosure.

It should be noted that the sequence of FIGS. 10A-10B may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.
Stage 1, as shown in FIG. 10A, illustrates a state after a carrier 1000 is provided and/or formed.
Stage 2 illustrates a state after a plurality of interconnects 1002 are formed on the carrier 1000. A plating process may be used to form the plurality of interconnects 1002. The plurality of interconnects 1002 may be formed on a seed layer (not shown) of the carrier 1000.
Stage 3 illustrates a state after a dielectric layer 1010 is formed over the carrier 1000. The dielectric layer 1010 may include a plurality of openings 1011. A deposition and/or lamination process may be used to form the dielectric layer 1010. The dielectric layer 1010 may include prepreg and/or Ajinomoto Build-up Film (ABF). The plurality of openings 1011 may be formed using an etching process (e.g., photo etching process) or laser process. For example, an exposure and development process may be used to form the plurality of openings 1011.
Stage 4 illustrates a state after a plurality of interconnects 1012 are formed in and over the dielectric layer 1010, including in and over the plurality of openings 1011. For example, via interconnects, pad interconnects and/or trace interconnects may be formed. A plating process may be used to form the interconnects. The plurality of interconnects 1012 may be coupled to the plurality of interconnects 1002.
Stage 5, as shown in FIG. 10B, illustrates a state after a dielectric layer 1020 is formed over the dielectric layer 1010. The dielectric layer 1020 may include a plurality of openings 1021. A deposition and/or lamination process may be used to form the dielectric layer 1020. The dielectric layer 1020 may include prepreg and/or Ajinomoto Build-up Film (ABF). The plurality of openings 1021 may be formed using an etching process (e.g., photo etching process) or laser process. For example, an exposure and development process may be used to form the plurality of openings 1021.
Stage 6 illustrates a state after a plurality of interconnects 1022 are formed in and over the dielectric layer 1020, including in and over the plurality of openings 1021. For example, via interconnects, pad interconnects and/or trace interconnects may be formed. A plating process may be used to form the interconnects. The plurality of interconnects 1022 may be coupled to the plurality of interconnects 1012.
Stage 7, illustrates a state after the carrier 1000 is removed. The carrier 1000 may be decoupled from the dielectric layer 1010 and/or the dielectric layer 1020. The carrier 1000 may be detached and/or peeled off from the dielectric layer 1010 and/or the dielectric layer 1020.
Stage 8, illustrates a state after a solder resist layer 124 and a solder resist layer 126 are formed and coupled to the dielectric layer 1010 and/or the dielectric layer 1020. A deposition process and/or a lamination process may be used to form the solder resist layer 124 and/or the solder resist layer 126. Stage 8 may illustrate the substrate 102 that includes at least one dielectric layer 120 and a plurality of interconnects 122. The at least one dielectric layer 120 may represent the dielectric layer 1010 and/or the dielectric layer 1020. The plurality of interconnects 122 may represent the plurality of interconnects 1002, the plurality of interconnects 1012 and/or the plurality of interconnects 1022.

In some implementations, a cavity may be formed in the substrate 102. The cavity may be similar to the cavity 148 of the substrate 104. The cavity may extend through the solder resist layer 124, the dielectric layer 120 and the solder resist layer 126 In some implementations, the substrate 104 with a cavity may be implemented and/or configured as the substrate 102 with a cavity, as described in the disclosure. Thus, the substrate 102 may be fabricated to include a cavity, and implemented to replace the substrate 104 described in the disclosure.

### Exemplary Electronic Devices

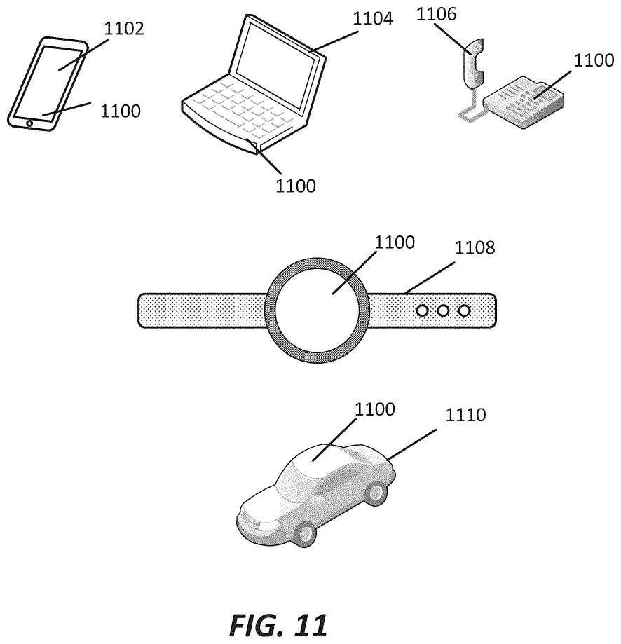

FIG. 11 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 1102, a laptop computer device 1104, a fixed location terminal device 1106, a wearable device 1108, or automotive vehicle 1110 may include a device 1100 as described herein. The device 1100 may be, for example, any of the devices and/or integrated circuit (IC) packages described herein. The devices 1102, 1104, 1106 and 1108 and the vehicle 1110 illustrated in FIG. 11 are merely exemplary. Other electronic devices may also feature the device 1100 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-6, 7A-7E, 8, 9, 10A-10B, and 11 may be rearranged and/or combined into a single component, process, feature or function or embodied in several components, processes, or functions. Additional elements, components, processes, and/or functions may also be added without departing from the disclosure. It should also be noted FIGS. 1-6, 7A-7E, 8, 9, 10A-10B, and 11 and its corresponding description in the present disclosure is not limited to dies and/or ICs. In some implementations, FIGS. 1-6, 7A-7E, 8, 9, 10A-10B, and 11 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object that is coupled to another object may be coupled to at least part of the another object. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. A first component that is “located” in a second component may mean that the first component is “partially located” in the second component or “completely located” in the second component. A first component that is “embedded” in a second component may mean that the first component is “partially embedded” in the second component or “completely embedded” in the second component. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.
Aspect 1: A package comprising a first substrate; a first integrated device coupled to the first substrate through at least a first plurality of solder interconnects; a second substrate coupled to the first substrate through at least a second plurality of solder interconnects, wherein the second substrate includes a cavity; and an encapsulation layer located at least between the first substrate and the second substrate, wherein the encapsulation layer is coupled to the first substrate, the second substrate and the first integrated device.
Aspect 2: The package of aspect 1, wherein the encapsulation layer is located in at least part of the cavity of the second substrate.
Aspect 3: The package of aspects 1 through 2, wherein the encapsulation layer encapsulates at least part of the first integrated device.
Aspect 4: The package of aspects 1 through 3, wherein the second substrate includes a solder resist layer, and wherein part of the encapsulation layer is located over the solder resist layer.
Aspect 5: The package of aspects 1 through 4, further comprising a second integrated device coupled to the first integrated device through at least a third plurality of solder interconnects.
Aspect 6: The package of aspect 5, wherein a front side of the second integrated device faces a back side of the first integrated device.
Aspect 7: The package of aspect 5 through 6, wherein the encapsulation layer encapsulates at least part of the first integrated device and at least part of the second integrated device.
Aspect 8: The package of aspects 5 through 7, wherein the first integrated device and/or the second integrated device are located at least partially in the cavity of the second substrate.
Aspect 9: The package of aspects 5 through 8, further comprising a thermal interface material coupled to the second integrated device; and a heat sink coupled to the second integrated device through the thermal interface material.
Aspect 10: The package of aspect 9, wherein the first integrated device, the second integrated device and/or the heat sink are located at least partially in the cavity of the second substrate.
Aspect 11: The package of aspects 9 through 10, wherein the heat sink is coupled to a back side of the second integrated device through the thermal interface material.
Aspect 12: The package of aspects 9 through 11, further comprising a third integrated device coupled to the second substrate through a fourth plurality of solder interconnects.
Aspect 13: The package of aspects 5 through 11, further comprising a third integrated device coupled to the second substrate through a fourth plurality of solder interconnects.
Aspect 14: The package of aspects 1 through 4, further comprising a second integrated device coupled to the second substrate through a third plurality of solder interconnects
Aspect 15: The package of aspects 1 through 14, wherein the second substrate includes an interposer comprising a plurality of interposer interconnects.
Aspect 16: The package of aspects 1 through 15, wherein the first integrated device comprises a die substrate, wherein the die substrate includes a thickness in a range of about 32-792 micrometers, and wherein the first integrated device includes a thickness in a range of about 40-800 micrometers.
Aspect 17: The package of aspect 16, wherein the first substrate includes a thickness in a range of about 100-300 micrometers, and wherein the second substrate includes a thickness in a range of about 50-150 micrometers, and wherein the encapsulation layer includes a thickness in a range of about 100-300 micrometers.
Aspect 18: The package of aspects 1 through 17, wherein the die substrate includes a plurality of through substrate vias.
Aspect 19: The package of aspects 1 through 18, wherein the die substrate includes a plurality of dummy through substrate vias.
Aspect 20: The package of aspects 1 through 19, wherein the package is implemented in a device that is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a first substrate;
a first integrated device coupled to the first substrate through at least a first plurality of solder interconnects;
a second substrate coupled to the first substrate through at least a second plurality of solder interconnects, wherein the second substrate includes a cavity; and
an encapsulation layer located at least between the first substrate and the second substrate, wherein the encapsulation layer is coupled to the first substrate, the second substrate and the first integrated device.

2. The package of claim 1, wherein the encapsulation layer is located in at least part of the cavity of the second substrate.

3. The package of claim 1, wherein the encapsulation layer encapsulates at least part of the first integrated device.

4. The package of claim 1,
wherein the second substrate includes a solder resist layer, and
wherein part of the encapsulation layer is located over the solder resist layer.

5. The package of claim 1, further comprising a second integrated device coupled to the first integrated device through at least a third plurality of solder interconnects.

6. The package of claim 5, wherein a front side of the second integrated device faces a back side of the first integrated device.

7. The package of claim 5, wherein the encapsulation layer encapsulates at least part of the first integrated device and at least part of the second integrated device.

8. The package of claim 5, wherein the first integrated device and/or the second integrated device are located at least partially in the cavity of the second substrate.

9. The package of claim 5, further comprising:
a thermal interface material coupled to the second integrated device; and
a heat sink coupled to the second integrated device through the thermal interface material.

10. The package of claim 9, wherein the first integrated device, the second integrated device and/or the heat sink are located at least partially in the cavity of the second substrate.

11. The package of claim 9, wherein the heat sink is coupled to a back side of the second integrated device through the thermal interface material.

12. The package of claim 9, further comprising a third integrated device coupled to the second substrate through a fourth plurality of solder interconnects.

13. The package of claim 5, further comprising a third integrated device coupled to the second substrate through a fourth plurality of solder interconnects.

14. The package of claim 1, further comprising a second integrated device coupled to the second substrate through a third plurality of solder interconnects.

15. The package of claim 1, wherein the second substrate includes an interposer comprising a plurality of interposer interconnects.

16. The package of claim 1,
wherein the first integrated device comprises a die substrate,
wherein the die substrate includes a thickness in a range of about 32-792 micrometers, and
wherein the first integrated device includes a thickness in a range of about 40-800 micrometers.

17. The package of claim 16,
wherein the first substrate includes a thickness in a range of about 100-300 micrometers, and
wherein the second substrate includes a thickness in a range of about 50-150 micrometers, and
wherein the encapsulation layer includes a thickness in a range of about 100-300 micrometers.

18. The package of claim 1, wherein a die substrate from the first integrated device includes a plurality of through substrate vias.

19. The package of claim 1, wherein a die substrate from the first integrated device includes a plurality of dummy through substrate vias.

20. The package of claim 1, wherein the package is implemented in a device that is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.
